(19) United States
(12) Patent Application Publication
(10) Pub. No.: US 2026/0059972 A1
(43) Pub. Date: Feb. 26, 2026

(54) DISPLAY DEVICE, METHOD OF MANUFACTURING THE SAME, AND ELECTRONIC DEVICE COMPRISING THE SAME

(71) Applicant: Samsung Display Co., Ltd., Yongin-Si (KR)

(72) Inventors: Young Min KIM, Yongin-si (KR); Shin Tack KANG, Yongin-si (KR); Soon Kyeong KWON, Yongin-si (KR); Hyun Woo NOH, Yongin-si (KR); Moon Jung BAEK, Yongin-si (KR); Dae Ho LEE, Yongin-si (KR); Su Ji HAN, Yongin-si (KR)

(21) Appl. No.: 19/226,145

(22) Filed: Jun. 3, 2025

(30) Foreign Application Priority Data
Aug. 22, 2024 (KR) 10-2024-0113123

(51) Int. Cl. H10K 59/80; G02B 27/01; H10K 59/12; H10K 59/122

(52) U.S. Cl. CPC H10K 59/871; G02B 27/0172; H10K 59/1201; H10K 59/122; G02B 2027/0178

(57) ABSTRACT

A display device is disclosed that includes a substrate, a first electrode, a pixel defining layer, a first protective layer, a second protective layer, a light emitting layer, and a second electrode. The first electrode is positioned on the substrate. The pixel defining layer overlaps an edge region of the first electrode. The first protective layer is positioned between the first electrode and the pixel defining layer and overlaps the edge region of the first electrode. The second protective layer is positioned between the first protective layer and the pixel defining layer and overlaps the edge region of the first electrode. The light emitting layer is positioned on the first electrode. The second electrode is positioned on the light emitting layer. The second protective layer has a smaller cross-sectional width than the first protective layer. The first protective layer and the second protective layer include different materials.

This application claims priority to and the benefit of Korean Patent Application No. 10-2024-0113123 filed in the Korean Intellectual Property Office on Aug. 22, 2024, the entire contents of which are incorporated herein by reference.

### BACKGROUND

### (a) Field

The present disclosure relates to a display device, a method of manufacturing the same, and an electronic device comprising the same, and more particularly to a display device that is capable of preventing current leakage, and a method of manufacturing the same, and an electronic device comprising the same.

### (b) Description of the Related Art

A display device is a device for displaying images to provide visual information to a user. Recently, a head mounted display (HMD) including the display device has been developed. The head-mounted display is a virtual reality (VR) or augmented reality (AR) eyewear-type monitor device that is worn in the form of glasses, a helmet, or the like to form a focal point immediately in front of the user's eyes. A head-mounted display may present the image displayed on the display device to the user's eyes through a lens.

### SUMMARY

The present disclosure may provide a display device capable of preventing current leakage in a vertical direction, a method of manufacturing the same, and an electronic device comprising the same.

An embodiment of a display device includes: a substrate; a first electrode positioned on the substrate; a pixel defining layer overlapping an edge region of the first electrode; a first protective layer positioned between the first electrode and the pixel defining layer and overlapping the edge region of the first electrode; a second protective layer positioned between the first protective layer and the pixel defining layer and overlapping the edge region of the first electrode; a light emitting layer positioned on the first electrode; and a second electrode positioned on the light emitting layer, in which a width of the second protective layer is smaller than a width of the first protective layer in a cross-sectional view, and the first protective layer and the second protective layer include different materials.

The first protective layer may include an insulating material.

The first protective layer may include a metal oxide.

The metal oxide may include a first metal oxide selected from aluminum oxide (Al₂O₃), tantalum oxide (Ta₂O₅), zirconium oxide (ZrO₂), and a combination thereof.

The second protective layer may include a metal.

The metal may include a first metal selected from aluminum (Al), copper (Cu), silver (Ag), gold (Au), platinum (Pt), palladium (Pd), nickel (Ni), molybdenum (Mo), tungsten (W), titanium (Ti), chromium (Cr), tantalum (Ta), and a combination thereof.

The second protective layer may include a transparent conductive oxide (TCO).

The TCO may include a first TCO selected from indium tin oxide (ITO), poly-ITO, indium zinc oxide (IZO), indium gallium zinc oxide (IGZO), indium tin zinc oxide (ITZO), fluorine-doped tin oxide (FTO), aluminum-doped zinc oxide (AZO), and a combination thereof.

The pixel defining layer may have an undercut shape by the second protective layer.

An inner edge of the first protective layer may be aligned with an edge of the pixel defining layer.

The first protective layer may be in contact with the light emitting layer.

The second protective layer may be spaced apart from the light emitting layer.

The light emitting layer may include a plurality of light emitting units.

The light emitting layer may include a first light emitting unit, a second light emitting unit, and a third light emitting unit, and the first light emitting unit, the second light emitting unit, and the third light emitting unit may emit red light, green light, and blue light, respectively.

An embodiment of a method of manufacturing a display device includes: preparing a substrate; forming a first electrode on the substrate; forming a first material layer on the first electrode; forming a second material layer on the first material layer; forming a pixel defining layer on the substrate to overlap an edge region of the first electrode, an edge region of the first material layer, and an edge region of the second material layer; etching the second material layer to expose the first material layer; forming a first protective layer exposing the first electrode by etching the first material layer; form a second protective layer by additionally etching the second material layer; and sequentially forming a light emitting layer and a second electrode on an entire surface of the substrate, in which the first protective layer and the second protective layer include different materials.

The first protective layer may include an insulating material.

The second protective layer may include at least one of a metal and a transparent conductive oxide.

The etching of the second material layer to expose the first material layer may use a dry etching process.

The forming the first protective layer may include a wet etching process, and an inner edge of the first protective layer may be aligned with an edge of the pixel defining layer.

The forming the second protective layer may include a wet etching process, and a width of the second protective layer may be smaller than a width of the first protective layer a cross-sectional view.

The display device according to the embodiment may prevent a short of the first electrode and the second electrode, thereby preventing current leakage in the vertical direction.

### BRIEF DESCRIPTION OF THE DRAWINGS

FIG. 1 is a schematic perspective view of a display device according to an embodiment.

FIG. 2 is a cross-sectional view of a display unit of the display device according to the embodiment.

FIG. 3 is a cross-sectional view of a light emitting element of the display device according to the embodiment.

FIGS. 4 to 10 are process cross-sectional views sequentially illustrating a method of manufacturing a display device according to an embodiment.

### DETAILED DESCRIPTION

In the following detailed description, only certain embodiments of the present disclosure have been illustrated and described, simply by way of illustration. The present disclosure may be variously implemented and is not limited to the following embodiments.

The drawings and description are to be regarded as illustrative in nature and not restrictive. Like reference numerals designate like elements throughout the specification.

In addition, the size and thickness of each configuration illustrated in the drawings are arbitrarily illustrated for understanding and ease of description, but the present disclosure is not limited thereto. In the drawings, the thickness of layers, films, panels, regions, etc., are exaggerated for clarity. In the drawings, for understanding and ease of description, the thickness of some layers and areas is exaggerated.

Further, it will be understood that when an element such as a layer, film, region, or substrate is referred to as being “on” another element, it may be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above”or “on”in a direction opposite to gravity.

In addition, in the entire specification, unless explicitly described to the contrary, the words “comprise” and “include” (as well as variations such as “comprises” and “comprising”) will be understood to imply the inclusion of stated elements but not the exclusion of any other elements.

Further, in the entire specification, when it is referred to as “in a plan view”, it means when a target part is viewed from above, and when it is referred to as “in a cross-sectional view”, it means when the cross-section obtained by cutting a target part vertically is viewed from the side.

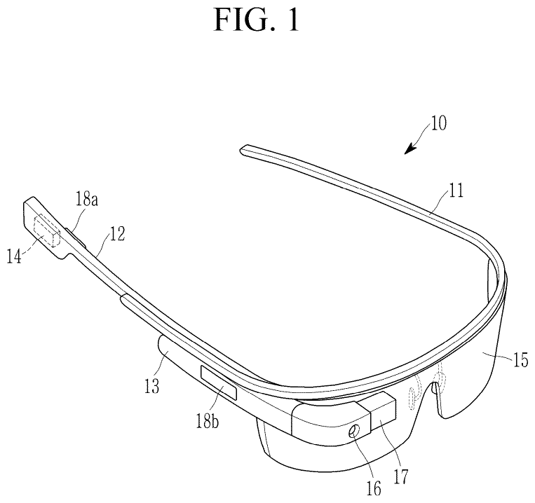

FIG. 1 is a schematic perspective view of a display device according to an embodiment.

A display device according to an embodiment is a device for displaying video or still images and may be used as a display screen for a variety of products, including portable electronic devices, such as mobile phones, smart phones, tablet personal computers (PC), mobile communication terminals, electronic notebooks, e-books, portable multimedia players (PMPs), navigation systems, ultra mobile PCs (UMPCs), and the like, as well as televisions, laptops, monitors, billboards, and the internet of things (IOT). In addition, the display device according to the embodiment may be used in wearable devices, such as smart watches, watch phones, eyewear displays, and head mounted displays (HMDs). In addition, the display device according to the embodiment may be used as a center information display (CID) disposed on an instrument panel of a vehicle, and on a center fascia or dashboard of a vehicle, as a room mirror display in place of a side mirror of a vehicle, and as a display disposed on a back surface of a front seat of a vehicle for entertainment for a rear seat of the vehicle. For ease of illustration, FIG. 1 shows the display device being used as a wearable device.

The wearable device 10 is configured to be worn on a head of a human body and may include a frame part (case, housing, etc.) for this purpose. The frame part may be formed of a flexible material to facilitate wearing.

Referring to FIG. 1, an example is given in which the frame part includes a first frame 11 and a second frame 12 made of different materials. The frame part is supported on a head of a user and provides space for mounting various components. As shown, the frame part may be equipped with electronic components, such as a control module 13 and an acoustic output module 14.

The control module 13 is configured to control various electronic components provided in the wearable device 10. In the illustrated embodiment, the control module 13 is part of or attached to the second frame 12. However, the location of the control module 13 is not limited thereto.

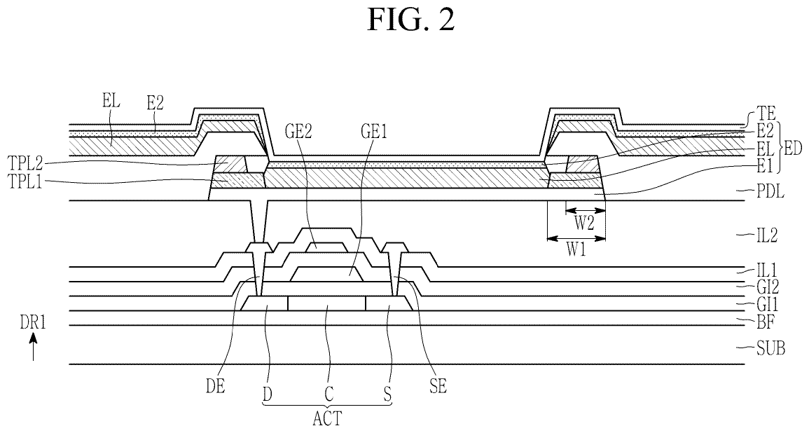

The display unit 15 may be implemented in the form of a head mounted display (HMD). The HMD may be a display scheme in which a device is mounted on the head of the user and displays images directly in front of the user's eyes. The display unit 15 may be disposed to correspond to at least one of the left eye and the right eye so that the image may be provided directly in front of the user's eyes when the user wears the glasses-type wearable device 10. The display unit 15 may include a pixel in the form described in FIG. 2 below.

The image output through the display unit 15 may provide virtual reality (VR). The present disclosure is not limited thereto, and, the image output through the display unit 15 may also provide augmented reality (AR), in which a virtual image is superimposed on a real-world image or background to provide a single image.

The wearable device 10 may include lenses corresponding to the user's two eyes. These lenses may be configured as fisheye lenses, wide-angle lenses, or the like to increase the user's field of view (FOV).

A camera 16 is disposed adjacent to at least one of the left eye and the right eye, and is configured to capture an image of the front. Since the camera 16 is positioned adjacent to the eye, the camera 16 may acquire an image of the scene that the user is looking at.

A gaze detection sensor 17 is disposed adjacent to at least one of the left eye and the right eye, and is configured to detect gaze from at least one of the left eye and the right eye of the user.

The wearable device 10 may include user input units 18a and 18b operable to receive control commands.

Hereinafter, a display device according to an embodiment will be described with reference to FIG. 2. FIG. 2 is a cross-sectional view of a portion of the display unit of the display device according to the embodiment.

Referring to FIG. 2, a substrate SUB may include a material having rigid properties, such as glass, or a flexible material that may be bent, such as plastic and polyimide.

A buffer layer BF may be positioned on top of the substrate SUB. The buffer layer BF may flatten the surface of the substrate SUB and block the penetration of impure elements. The buffer layer BF may include an inorganic material, for example, an inorganic insulating material, such as silicon nitride (SiNx), silicon oxide (SiOx), and silicon nitrate (SiOxNy). Depending on the embodiment, the buffer layer BF may be a single layer or multilayer structure including different-phase inorganic insulating materials.

A semiconductor layer ACT may be positioned on top of the buffer layer BF. The semiconductor layer ACT may include any one of amorphous silicon, polycrystalline silicon, and oxide semiconductors. For example, the semiconductor layer ACT may include low temperature polysilicon (LTPS) or an oxide semiconductor including at least one of zinc (Zn), indium (In), gallium (Ga), tin (Sn), and mixtures thereof. For example, the semiconductor layer ACT may include indium-gallium-zinc oxide (IGZO). The semiconductor layer ACT may include a channel region C, a source region S, and a drain region D, which are distinguished by whether they are doped with impurities or not. The source region S and the drain region D may have conductive properties corresponding to conductors.

A first gate insulation film GI1 may be positioned above the semiconductor layer ACT. The first gate insulation film GI1 may cover the semiconductor layer ACT and the substrate SUB. The first gate insulation film GI1 may include an inorganic insulating material, such as silicon nitride (SiNx), silicon oxide (SiOx), and silicon nitrate (SiOxNy). The first gate insulation film GI1 may be a single layer or multilayer structure including different-phase inorganic insulating materials.

A gate electrode GE1 may be positioned on top of the first gate insulation film GI1. The gate electrode GE1 may include a metal or metal alloy, such as copper (Cu), molybdenum (Mo), aluminum (Al), silver (Ag), chromium (Cr), tantalum (Ta), and titanium (Ti). The gate electrode GE1 may be formed in a single layer or multiple layers. A region of the semiconductor layer ACT that overlaps the gate electrode GE1 in-plane may be the channel region C.

A second gate insulation film GI2 may be positioned above the gate electrode GE1. The second gate insulation film GI2 may include an inorganic insulating material, such as silicon nitride (SiNx), silicon oxide (SiOx), and silicon nitrate (SiOxNy). The second gate insulation film GI2 may be a single layer or multilayer structure including different-phase inorganic insulating materials.

A capacitor electrode GE2 may be positioned on top of the second gate insulation film GI2. The capacitor electrode GE2 may overlap the gate electrode GE1 and form a capacitor.

A first insulation film IL1 may be positioned on the capacitor electrode GE2. The first insulation film IL1 may include an inorganic insulating material, such as silicon nitride (SiNx), silicon oxide (SiOx), and silicon nitrate (SiOxNy). The first insulation film IL1 may be a single layer or multilayer structure including different-phase inorganic insulating materials.

A source electrode SE and a drain electrode DE may be positioned on the first insulation film IL1. The source electrode SE and the drain electrode DE are electrically connected to the source region S and the drain region D of the semiconductor layer ACT by openings formed in the first insulation film IL1, the second gate insulation film GI2, and the first gate insulation film GI1, respectively. Accordingly, the semiconductor layer ACT, the gate electrode GE, the source electrode SE, and the drain electrode DE form a single transistor. Depending on the embodiment, the transistor may include only the source region and the drain region of the semiconductor layer ACT instead of the source electrode SE and the drain electrode DE.

The source electrode SE and the drain electrode DE may include metals or metal alloys, such as aluminum (Al), copper (Cu), silver (Ag), gold (Au), platinum (Pt), palladium (Pd), nickel (Ni), molybdenum (Mo), tungsten (W), titanium (Ti), chromium (Cr), and tantalum (Ta). The source electrode SE and the drain electrode DE may include a single layer or multiple layers. The source electrode SE and the drain electrode DE according to the embodiment may include a triple layer including a top layer, a middle layer, and a bottom layer, in which the top layer and the bottom layer may include titanium (Ti) and the middle layer may include aluminum (Al).

A second insulation film IL2 may be positioned on the source electrode SE and the drain electrode DE. The second insulation film IL2 covers the source electrode SE and the drain electrode DE. The second insulation film IL2 may flatten the surface of the substrate SUB on which the transistors are mounted. The second insulation film IL2 may be an organic insulation film, and may include one or more materials selected from the group consisting of polyimide, polyamide, acrylic resin, benzocyclobutene, and phenolic resin.

A first electrode E1 may be positioned on top of the second insulation film IL2. The first electrode E1, also referred to as the anode electrode, may include a single layer or multiple layers including a transparent conductive oxide film or metallic material. The transparent conductive oxide film may include indium tin oxide (ITO), poly-ITO, indium zinc oxide (IZO), indium gallium zinc oxide (IGZO), and indium tin zinc oxide (ITZO). The metal material may include silver (Ag), molybdenum (Mo), copper (Cu), gold (Au), aluminum (Al), and the like. For example, the first electrode E1 may have a three-layer structure of ITO/Ag/ITO.

The first electrode E1 may be physically and electrically connected to the drain electrode DE through an opening in the second insulation film IL2. Accordingly, the first electrode E1 may receive an output current from the drain electrode DE to be delivered to a light emitting layer EL.

A pixel defining layer PDL may be positioned on the second insulation film IL2. The pixel defining layer PDL may overlap at least a portion of the first electrode E1. With respect to the first direction DR1, which is a direction perpendicular to the substrate SUB, the pixel defining layer PDL may overlap an edge region of the first electrode E1 and may be spaced apart from a center of the first electrode E1. The pixel defining layer PDL may compartmentalize the formation location of the light emitting layer EL, such that the light emitting layer EL is positioned on the exposed top surface of the first electrode E1. The pixel defining layer PDL may be an organic insulation film including one or more materials selected from the group consisting of polyimide, polyamide, acrylic resin, benzocyclobutene, and phenolic resin.

A first protective layer TPL1 may be positioned on the first electrode E1. The first protective layer TPL1 may be positioned between the first electrode E1 and the pixel defining layer PDL. With respect to the first direction DR1, the first protective layer TPL1 may overlap the edge region of the first electrode E1 and the pixel defining layer PDL, and may be spaced apart from the center of the first electrode E1. Inner edges of the first protective layer TPL1 facing each other in a cross-sectional view and edges of the pixel defining layer PDL facing each other in a cross-sectional view may be aligned with respect to the first direction DR1.

The first protective layer TPL1 may include an insulating material, for example, a metal oxide, such as aluminum oxide (Al₂O₃), tantalum oxide (Ta₂O₅), and zirconium oxide (ZrO₂).

The first protective layer TPL1 may be positioned on the edge region of the first electrode E1 to prevent a short between the first electrode E1 and the second electrode E2. Thus, vertical current leakage may be prevented.

A second protective layer TPL2 may be positioned on the first protective layer TPL1. The second protective layer TPL2 may be positioned between the first protective layer TPL1 and the pixel defining layer PDL. With respect to the first direction DR1, the second protective layer TPL2 may overlap the edge region of the first electrode E1, the first protective layer TPL1, and the pixel defining layer PDL, and may be spaced apart from the center of the first electrode E1. The pixel defining layer PDL may have an undercut shape by the second protective layer TPL2. A width W2 of the second protective layer TPL2 may be smaller than a width W1 of the first protective layer TPL1 in a cross-sectional view. A width may be a length in a direction perpendicular to the first direction DR1 in a cross-sectional view. Furthermore, the inner edges of the first protective layer TPL1 that face each other in a cross-sectional view may protrude further than inner edges of the second protective layer TPL2 that face each other in a cross-sectional view.

The second protective layer TPL2 may include metal materials, such as aluminum (Al), copper (Cu), silver (Ag), gold (Au), platinum (Pt), palladium (Pd), nickel (Ni), molybdenum (Mo), tungsten (W), titanium (Ti), chromium (Cr), and tantalum (Ta). Further, the second protective layer TPL2 may include a transparent conductive oxide (TCO), such as indium tin oxide (ITO), poly-ITO, indium zinc oxide (IZO), indium gallium zinc oxide (IGZO), indium tin zinc oxide (ITZO), fluorine-doped tin oxide (FTO), and aluminum-doped zinc oxide (AZO).

The second protective layer TPL2 and the pixel defining layer PDL having the undercut shape by the second protective layer TPL2 may prevent a short between the first electrode E1 and the second electrode E2, and thus prevent current leakage in the vertical direction.

The first protective layer TPL1 and the second protective layer TPL2 may include different materials. Accordingly, the etch selectivity of the first protective layer TPL1 and the second protective layer TPL2 may be different.

The light emitting layer EL may be positioned on the first electrode E1. The light emitting layer EL may be positioned on the portion of the top surface of the first electrode E1 exposed by the pixel defining layer PDL. The light emitting layer EL may be in contact with the first protective layer TPL1 and spaced apart from the second protective layer TPL2 without contact.

A portion of the light emitting layer EL may be positioned on the first electrode E1 and another portion may be positioned on the pixel defining layer PDL. The light emitting layer EL positioned on the first electrode E1 and the light emitting layer EL positioned on the pixel defining layer PDL may be formed in the same process and may include the same material. The light emitting layer EL positioned on the first electrode E1 and the light emitting layer EL positioned on the pixel definition layer PDL may be spaced apart from each other. A portion that is substantially emitting light may correspond to the light emitting layer EL positioned on the first electrode E1.

The second electrode E2 may be positioned on the pixel defining layer PDL and the light emitting layer EL. The second electrode E2 may also be referred to as a cathode electrode. The second electrode E2 may be electrically insulated from the first electrode E1 by the first protective layer TPL1, the second protective layer TPL2, and the pixel defining layer PDL. Thus, vertical current leakage may be prevented. The second electrode E2 may be disconnected by the pixel defining layer PDL. The second electrode E2 positioned on the pixel defining layer PDL and the second electrode E2 positioned on the light emitting layer EL may be disconnected from each other. The second electrode E2 positioned on the pixel defining layer PDL and the second electrode E2 positioned on the light emitting layer EL may be spaced apart from each other.

A transparent conductive layer TE may be positioned on the second electrode E2. The transparent conductive layer TE may include a transparent conductive oxide, such as indium tin oxide (ITO), poly-ITO, indium zinc oxide (IZO), indium gallium zinc oxide (IGZO), indium tin zinc oxide (ITZO), fluorine-doped tin oxide (FTO), and aluminum-doped zinc oxide (AZO). The transparent conductive layer TE may be a single and uninterrupted layer covering the second electrode E2.

The transparent conductive layer TE may be formed continuously on the entire surface of the substrate SUB. The transparent conductive layer TE may electrically connect the second electrode E2 positioned on the pixel defining layer PDL and the second electrode E2 positioned on the light emitting layer EL. The transparent conductive layer TE may deliver a common voltage for a plurality of pixels.

The first electrode E1, the light emitting layer EL, and the second electrode E2 may form a single light emitting device ED.

An encapsulation layer may be positioned on the second electrode E2. The encapsulation layer may include at least one inorganic film and at least one organic film.

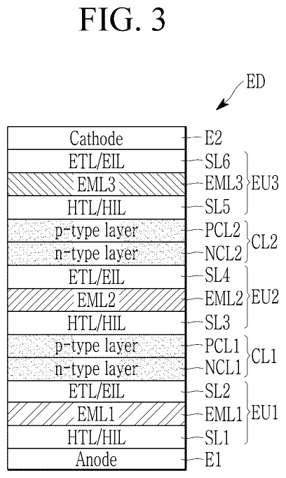

Hereinafter, an embodiment of the light emitting device will be described with reference to FIG. 3. FIG. 3 is a cross-sectional view schematically illustrating the structure of the light emitting device.

Referring to FIG. 3, the light emitting device ED of the display device according to the embodiment may include a plurality of light emitting units EU1, EU2, and EU3 disposed in series and a first charge generating layer CL1 and a second charge generating layer CL2 disposed between the plurality of light emitting units EU1, EU2, and EU3.

The light emitting device ED may include a first electrode E1, a first light emitting unit EU1, a first charge generating layer CL1, a second light emitting unit EU2, a second charge generating layer CL2, a third light emitting unit EU3, and a second electrode E2 arranged sequentially.

The structure is illustrated, in which the first electrode E1 is an anode electrode and the second electrode E2 is a cathode electrode, but the present disclosure is not limited thereto.

The first light emitting unit EU1 may include a first light emitting auxiliary layer SL1, a first main light emitting layer EML1, and a second light emitting auxiliary layer SL2. The second light emitting unit EU2 may include a third light emitting auxiliary layer SL3, a second main light emitting layer EML2, and a fourth light emitting auxiliary layer SL4. The third light emitting unit EU3 may include a fifth light emitting auxiliary layer SL5, a third main light emitting layer EML3, and a sixth light emitting auxiliary layer SL6.

The first light emitting auxiliary layers SL1, the third light emitting auxiliary layers SL3, and the fifth light emitting auxiliary layers SL5 may include at least one of a hole injection layer HIL and a hole transport layer HTL, and may include both a hole injection layer HIL and a hole transport layer HTL.

The second light emitting auxiliary layers SL2, the fourth light emitting auxiliary layers SL4, and the sixth light emitting auxiliary layers SL6 may include at least one of an electron transport layer ETL and an electron injection layer EIL, and may include both an electron injection layer EIL and an electron transport layer ETL.

The first charge generating layer CL1 and the second charge generating layer CL2 may include n-type layers NCL1 and CNL2 and p-type layers PCL1 and PCL2, respectively.

The light emitting device ED may be a white organic light emitting device (WOLED) emitting white light. Each of the first light emitting unit EU1, the second light emitting unit EU2, and the third light emitting unit EU3 may emit light having a color of any one of red, green, and blue. Two of the first light emitting unit EU1, the second light emitting unit EU2, and the third light emitting unit EU3 may emit blue light, and the other may emit yellow light. Further, two of the first light emitting unit EU1, the second light emitting unit EU2, and the third light emitting unit EU3 may emit yellow light and the other may emit blue light.

The present disclosure is not limited thereto, and, the first light emitting unit EU1, the second light emitting unit EU2, and the third light emitting unit EU3 may all emit any one of red, green, and blue light.

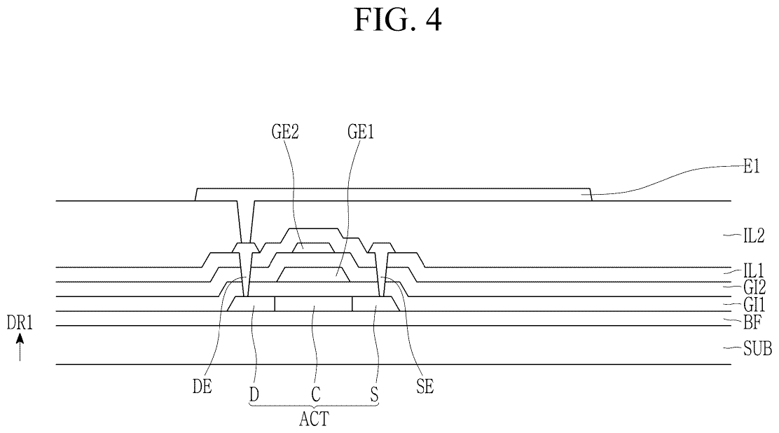

Hereinafter, with reference to FIGS. 4 to 10, a method of manufacturing a display device according to an embodiment will be described. FIGS. 4 to 10 are process cross-sectional views sequentially illustrating a method of manufacturing a display device according to an embodiment. A description of components that are identical to the components described above will be omitted.

Referring to FIG. 4, a first electrode E1 may be formed on a substrate SUB. The first electrode E1 may also be referred to as an anode electrode, for example, the first electrode E1 may have a three-layer structure of ITO/Ag/ITO.

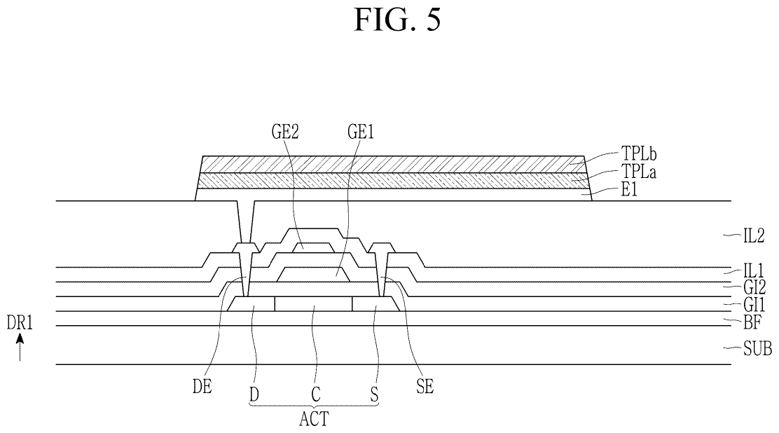

Referring to FIG. 5, a first material layer TPLa and a second material layer TPLb may be sequentially stacked on the first electrode E1. The first material layer TPLa may include an insulating material, for example, a metal oxide, such as aluminum oxide (Al₂O₃), tantalum oxide (Ta₂O₅), and zirconium oxide (ZrO₂). The second material layer TPLb may include metal materials, such as aluminum (Al), copper (Cu), silver (Ag), gold (Au), platinum (Pt), palladium (Pd), nickel (Ni), molybdenum (Mo), tungsten (W), titanium (Ti), chromium (Cr), and tantalum (Ta). Further, the second material layer TPLb may include a transparent conductive oxide (TCO), such as indium tin oxide (ITO), poly-ITO, indium zinc oxide (IZO), indium gallium zinc oxide (IGZO), indium tin zinc oxide (ITZO), fluorine-doped tin oxide (FTO), and aluminum-doped zinc oxide (AZO). The first material layer TPLa and the second material layer TPLb may include different materials. An etch selectivity of the first material layer TPLa and the second material layer TPLb may be different.

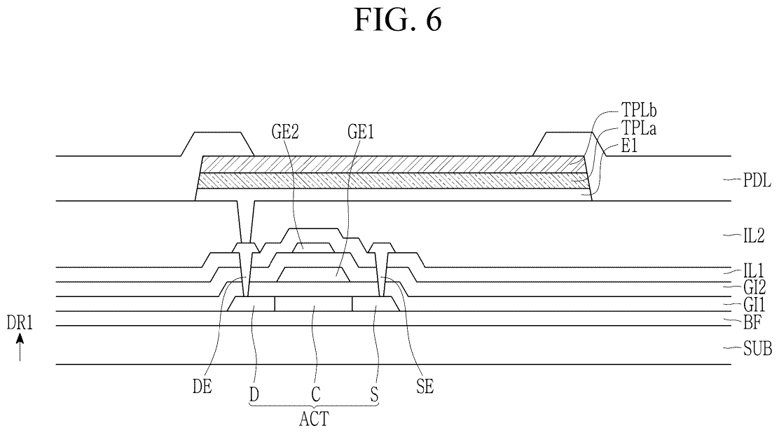

Referring to FIG. 6, a pixel defining layer PDL may be formed on the substrate SUB and the second material layer TPLb. With respect to the first direction DR1, the pixel defining layer PDL may overlap the edge region of the first electrode E1, the edge region of the first material layer TPLa, and the edge region of the second material layer TPLb. The pixel defining layer PDL may be spaced apart from the center of the first electrode E1, the center of the first material layer TPLa, and the center of the second material layer TPLb.

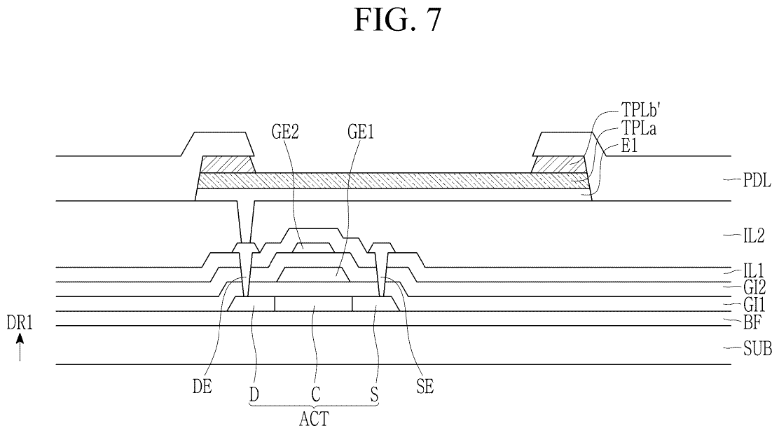

A second preliminary protective layer TPLb′ that exposes the first material layer TPLa of FIG. 7 may be formed by etching the second material layer TPLb. The etching of the second material layer TPLb may be performed by a dry etching process with the pixel defining layer PDL as a mask. By etching the second material layer TPLb, a portion of the second material layer TPLb that does not overlap the pixel defining layer PDL may be removed to form the second preliminary protective layer TPLb′. Inner edges of the second preliminary protective layer TPLb′ facing each other in a cross-sectional view and edges of the pixel defining layer PDL facing each other in a cross-sectional view may be aligned in the first direction DR1. The first material layer TPLa may prevent damage to the first electrode E1 when etching the second material layer TPLb.

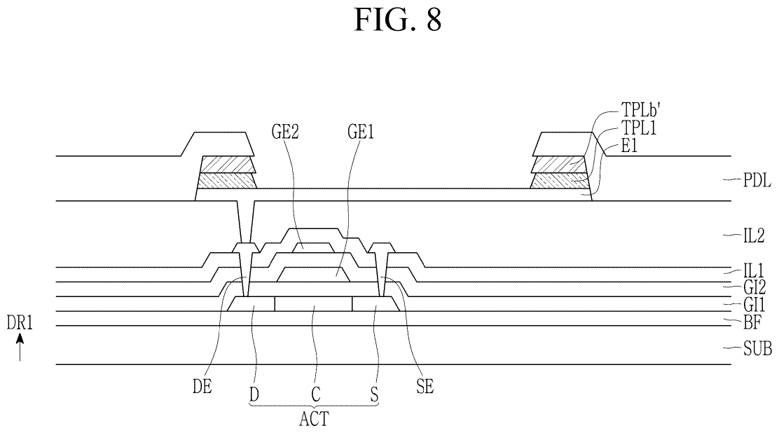

A first protective layer TPL1 that exposes the first electrode E1 of FIG. 8 may be formed by etching the first material layer TPLa. Etching of the first material layer TPLa may be performed by a wet etching process with the pixel defining layer PDL as a mask. The etching of the first material layer TPLa may be performed by using, for example, an etchant based on phosphoric acid (H₃PO₄). By not using fluorine-based etchant, damage to the first electrode E1 may be prevented. By etching the first material layer TPLa, a portion of the first material layer TPLa that does not overlap the pixel defining layer PDL may be removed to form the first protective layer TPL1. Inner edges of the first protective layer TPL1 facing each other in a cross-sectional view and edges of the pixel defining layer PDL facing each other in a cross-sectional view may be aligned in the first direction DR1. The first protective layer TPL1 may be positioned on the edge region of the first electrode E1 to prevent a short between the first electrode E1 and the second electrode E2.

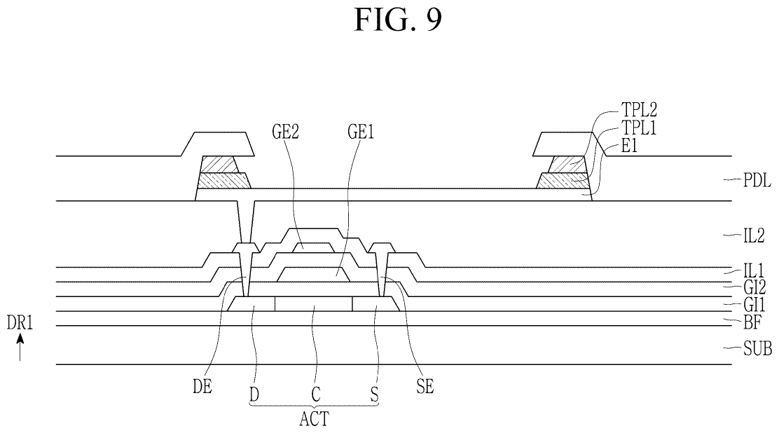

The second protective layer TPL2 of FIG. 9 may be formed by etching the second preliminary protective layer TPLb′. For example, the etching of the second preliminary protective layer TPLb′ may be performed by a wet etching process with the pixel defining layer PDL as a mask. The etching of the second preliminary protective layer TPLb′ may be performed by using, for example, an etchant based on phosphoric acid (H₃PO₄). The etch selectivity of the second preliminary protective layer TPLb′ may be greater than the etch selectivity of the first protective layer TPL1. Therefore, the width W2 of the second protective layer TPL2 may be smaller than the width W1 of the first protective layer TPL1 in a cross-sectional view. Furthermore, the inner edges of the first protective layer TPL1 that face each other in cross-section may protrude further than the inner edges of the second protective layer TPL2. The pixel defining layer PDL may have an undercut shape by the second protective layer TPL2. The second protective layer TPL2 and the pixel defining layer PDL having the undercut shape by the second protective layer TPL2 may prevent a short between the first electrode E1 and the second electrode E2, and thus prevent current leakage in the vertical direction.

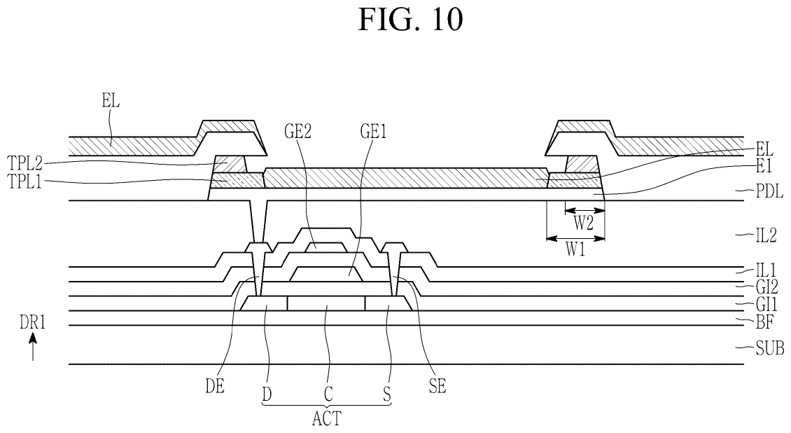

Referring to FIG. 10 in conjunction with FIG. 2, a light emitting layer EL and a second electrode E2 may be formed sequentially on an entire surface of the substrate SUB. The second electrode E2 may be electrically insulated from the first electrode E1 by the first protective layer TPL1, the second protective layer TPL2, and the pixel defining layer PDL. The second electrode E2 may be disconnected by the pixel defining layer PDL.

While the present disclosure has been described with reference to embodiments thereof, it will be apparent to those of ordinary skill in the art that various changes and modifications may be made thereto without departing from the scope and spirit of the present disclosure as set forth in the following claims.

What is claimed is:

1. A display device comprising:
a substrate;
a first electrode positioned on the substrate;
a pixel defining layer overlapping an edge region of the first electrode;
a first protective layer positioned between the first electrode and the pixel defining layer and overlapping the edge region of the first electrode;
a second protective layer positioned between the first protective layer and the pixel defining layer and overlapping the edge region of the first electrode;
a light emitting layer positioned on the first electrode; and
a second electrode positioned on the light emitting layer,
wherein a width of the second protective layer is smaller than a width of the first protective layer in a cross-sectional view, and
the first protective layer and the second protective layer include different materials.

2. The display device of claim 1, wherein:
the first protective layer includes an insulating material.

3. The display device of claim 2, wherein:
the first protective layer includes a metal oxide.

4. The display device of claim 3, wherein:
the metal oxide includes a first metal oxide which is selected from aluminum oxide (Al₂O₃), tantalum oxide (Ta₂O₅), zirconium oxide (ZrO₂), and a combination thereof.

5. The display device of claim 1, wherein:
the second protective layer includes a metal.

6. The display device of claim 5, wherein:
the metal includes a first metal selected from aluminum (Al), copper (Cu), silver (Ag), gold (Au), platinum (Pt), palladium (Pd), nickel (Ni), molybdenum (Mo), tungsten (W), titanium (Ti), chromium (Cr), tantalum (Ta), and a combination thereof.

7. The display device of claim 1, wherein:
the second protective layer includes a transparent conductive oxide (TCO).

8. The display device of claim 7, wherein:
the TCO includes a first TCO selected from indium tin oxide (ITO), poly-ITO, indium zinc oxide (IZO), indium gallium zinc oxide (IGZO), indium tin zinc oxide (ITZO), fluorine-doped tin oxide (FTO), aluminum-doped zinc oxide (AZO), and a combination thereof.

9. The display device of claim 1, wherein:
the pixel defining layer has an undercut shape by the second protective layer.

10. The display device of claim 1, wherein:
an inner edge of the first protective layer is aligned with an edge of the pixel defining layer.

11. The display device of claim 1, wherein:
the first protective layer is in contact with the light emitting layer, and the second protective layer is spaced apart from the light emitting layer.

12. The display device of claim 1, wherein:
the light emitting layer includes a plurality of light emitting units.

13. The display device of claim 1, wherein:
the light emitting layer includes a first light emitting unit, a second light emitting unit, and a third light emitting unit, and
the first light emitting unit, the second light emitting unit, and the third light emitting unit emit red light, green light, and blue light, respectively.

14. A method of manufacturing a display device, the method comprising:
preparing a substrate;
forming a first electrode on the substrate;
forming a first material layer on the first electrode;
forming a second material layer on the first material layer;
forming a pixel defining layer on the substrate to overlap an edge region of the first electrode, an edge region of the first material layer, and an edge region of the second material layer;
etching the second material layer to expose the first material layer;
forming a first protective layer exposing the first electrode by etching the first material layer;
forming a second protective layer by additionally etching the second material layer; and
sequentially forming a light emitting layer and a second electrode on an entire surface of the substrate,
wherein the first protective layer and the second protective layer include different materials.

15. The method of claim 14, wherein:
the first protective layer includes an insulating material.

16. The method of claim 14, wherein:
the second protective layer includes at least one of a metal and a transparent conductive oxide.

17. The method of claim 14, wherein:
the etching of the second material layer to expose the first material layer includes a dry etching process.

18. The method of claim 14, wherein:
the forming the first protective layer includes a wet etching process, and an inner edge of the first protective layer is aligned with an edge of the pixel defining layer.

19. The method of claim 14, wherein:
the forming the second protective layer includes a wet etching process, and
a width of the second protective layer is smaller than a width of the first protective layer in a cross-sectional.

20. An electronic device comprising a display device,
the display device comprising:
a substrate;
a first electrode positioned on the substrate;
a pixel defining layer overlapping an edge region of the first electrode;
a first protective layer positioned between the first electrode and the pixel defining layer and overlapping the edge region of the first electrode;
a second protective layer positioned between the first protective layer and the pixel defining layer and overlapping the edge region of the first electrode;
a light emitting layer positioned on the first electrode; and
a second electrode positioned on the light emitting layer,
wherein a width of the second protective layer is smaller than a width of the first protective layer in a cross-sectional view, and
the first protective layer and the second protective layer include different materials.
